(19) United States
(12) Patent Application Publication
(10) Pub. No.: US 2018/0269270 A1
(43) Pub. Date: Sep. 20, 2018

(54) SEMICONDUCTOR DEVICE

(71) Applicant: ABLIC Inc., Chiba-shi (JP)

(72) Inventor: Hisashi HASEGAWA, Chiba-shi (JP)

(21) Appl. No.: 15/916,012

(22) Filed: Mar. 8, 2018

(30) Foreign Application Priority Data
Mar. 14, 2017 (JP) 2017-048801
Nov. 8, 2017 (JP) 2017-215445

(51) Int. Cl. H01L 49/02; H01L 27/08

(52) U.S. Cl. CPC H01L 28/20; H01L 27/0802

(57) ABSTRACT

A semiconductor device includes: a bleeder resistor circuit element including a plurality of polycrystalline silicon resistor units; a first metal film divided into a plurality of films so as to individually cover the plurality of polycrystalline silicon resistor units; an integral second metal film for covering an entirety of the bleeder resistor circuit element; and a silicon nitride film formed above the second metal film. Each of the plurality of films of the first metal film includes a first part for covering an electrode portion of the polycrystalline silicon resistor unit, and a second part for covering a portion other than the electrode portion. The first part is electrically connected to the polycrystalline silicon resistor unit.

### RELATED APPLICATIONS

This application claims priority under 35 U.S.C. § 119 to Japanese Patent Application Nos. 2017-048801 filed on Mar. 14, 2017 and 2017-215445 filed on Nov. 8, 2017, the entire content of which are hereby incorporated by reference.

### BACKGROUND OF THE INVENTION

### 1. Field of the Invention

The present invention relates to a semiconductor device.

### 2. Description of the Related Art

An analog IC, for example, a voltage detector, includes a bleeder resistor circuit formed of thin film resistors made of, for example, polycrystalline silicon, so that desired characteristics are output by a combination of transistors and the resistors, and the bleeder resistor circuit has an adjusted resistance division ratio. An interlayer insulating film and a final protective film are formed on the thin film resistor. There has been known an issue in that, due to penetration of hydrogen that diffuses in a process of forming the final protective film and so on, the resistance division ratio of the bleeder resistor circuit varies within a wafer surface, resulting in a decrease in yield. In a general semiconductor device, a metal wire having a large area is arranged above the thin film resistor in a seamless manner to avoid the issue of penetration of hydrogen.

However, even when the metal wire having a large area is arranged as described above, for convenience of wiring, a metal wire for electrically connecting electrode portions of each resistor, that is, a metal wire for covering the electrode portions, is separated from the metal wire having a large area which covers high-resistance portions other than the electrode portions. Consequently, there is a gap between the separated metal wires, and it is difficult to also avoid penetration of hydrogen into the periphery of the electrode portion through the gap. The influence of penetration of hydrogen into the periphery of the electrode portion becomes conspicuous in a semiconductor device having a multilayer wiring structure which has complicated circuits mounted thereon.

Meanwhile, when the metal wire having a large area is arranged as described above, there is also an issue in that a resistance value changes at different ratios for each resistor unit forming the bleeder resistor circuit. This issue is caused by the fact that the potential of each resistor unit, which is determined by the power supply voltages (V_{dd} and Vₛₛ), differs depending on the distance from the power supply, and hence the potential difference from a grounded metal wire differs between the resistor units. For example, a resistor unit positioned on a low potential side (Vₛₛ) has a small potential difference from the metal wire, and hence the resistance value change thereof is small. Meanwhile, a resistor unit positioned on a high potential side (V_{dd}) has a large potential difference from the metal wire, and hence the resistance value change thereof is large. The variation in resistance value change between the resistor units becomes conspicuous when the power supply voltage is increased, and hence there is a demand for countermeasures against this issue.

In Japanese Patent No. 3526701, as one of countermeasures against the variation in resistance value change, there is disclosed a configuration in which a metal wire is divided so as to correspond to each resistor unit, and each of the divided metal wires is electrically connected to the corresponding resistor unit. With this configuration, there is no potential difference between the resistor unit and the metal wire, and hence the issue of the variation in resistance value change can be avoided.

However, with this configuration, a gap may be formed between the divided metal wires. Consequently, there is a risk in that hydrogen that has passed through the gap may disturb the resistance division ratio of the bleeder resistor circuit, and hence there is room for improvement of the configuration.

### SUMMARY OF THE INVENTION

The present invention has been made in view of the above-mentioned circumstances, and an object of the present invention is to provide a semiconductor device capable of preventing penetration of hydrogen into an entire bleeder resistor circuit including electrode portions and suppressing a variation in resistance value change between the resistor units forming the bleeder resistor circuit.

In view of the foregoing, the present invention adopts the following means.

(1) According to one embodiment of the present invention, there is provided a semiconductor device including: a substrate; a bleeder resistor circuit element formed on one main surface side of the substrate, and including a plurality of polycrystalline silicon resistor units; a first metal film divided into a plurality of films so as to individually cover the plurality of polycrystalline silicon resistor units; an integral second metal film formed above the first metal film so as to cover an entirety of the bleeder resistor circuit element; and a silicon nitride film formed above the integral second metal film. Each of the plurality of films of the first metal film includes a first part for covering an electrode portion of a corresponding one of the plurality of polycrystalline silicon resistor units, and a second part for covering a portion other than the electrode portion. The second part is electrically connected to the corresponding one of the plurality of polycrystalline silicon resistor units that is covered with the each of the plurality of films of the first metal film.

(2) According to one or more embodiments, in the semiconductor device as described in Item (1), the integral second metal film has an outermost periphery located on an outer side of an outermost periphery of the bleeder resistor circuit element in plan view from the silicon nitride film side.

(3) According to one or more embodiments, the semiconductor device as described in Item (1) or (2) further includes a side wall portion which is formed upright on a periphery of the bleeder resistor circuit element and is connected to the integral second metal film.

(4) According to one or more embodiments, the semiconductor device as described in any one of Items (1) to (3) has a first connection hole for connecting the substrate and the first metal film to each other, and a second connection hole for connecting the first metal film and the integral second metal film to each other, and the side wall portion is formed of a metal film embedded in the first connection hole and a metal film embedded in the second connection hole.

(5) According to one or more embodiments, the semiconductor device as described in Item (3) or (4) further includes, in plan view, a polycrystalline silicon cover in a region between a region in which the bleeder resistor circuit element is formed and a region in which the side wall portion is formed.

The above-mentioned semiconductor device includes the plurality of first metal films that are individually connected to the plurality of polycrystalline silicon resistor units, and further includes the second metal film having a large area, for covering the entirety of the bleeder resistor circuit element with the first metal films interposed between the second metal film and the bleeder resistor circuit element. Through arrangement of the first metal film, the potential difference between the polycrystalline silicon resistor unit and the first metal film is constant irrespective of the layout of components. As a result, the issue of the variation in resistance value change between the polycrystalline silicon resistor units can be avoided.

Further, through arrangement of the second metal film, the issue of penetration of hydrogen into the bleeder resistor circuit element can be avoided in a manufacturing process. As a result, in the above-mentioned semiconductor device, the amount of hydrogen contained in the bleeder resistor circuit element is significantly reduced as compared to the related art.

The second metal film is formed on an upper layer side of the first metal film. The second metal film is not required to be divided for the electrode portion and the high-resistance portion of the corresponding polycrystalline silicon resistor unit unlike the first metal film, and can be formed into a shape covering the entire bleeder resistor circuit including the periphery of the electrode portions without a gap. Consequently, in the above-mentioned semiconductor device, a hydrogen penetration path to an end portion of the polycrystalline silicon resistor at which the electrode portion is formed, as well as a hydrogen penetration path to a center portion of the polycrystalline silicon resistor can be shielded, with the result that a decrease in yield associated with the disturbance of the resistance division ratio of the bleeder resistor circuit element can be prevented.

### BRIEF DESCRIPTION OF THE DRAWINGS

FIG. 1 is a plan view of a semiconductor device according to a first embodiment of the present invention.

FIG. 2A and FIG. 2B are each a sectional view of the semiconductor device of FIG. 1.

FIG. 3 is a diagram of a bleeder resistor circuit forming the semiconductor device of FIG. 1, FIG. 2A, and FIG. 2B.

FIG. 4 is a plan view of a semiconductor device according to a second embodiment of the present invention.

FIG. 5 is a sectional view of the semiconductor device of FIG. 4.

FIG. 6 is a plan view of a semiconductor device according to a third embodiment of the present invention.

FIG. 7A and FIG. 7B are each a sectional view of the semiconductor device of FIG. 6.

### DETAILED DESCRIPTION OF THE EMBODIMENTS

The present invention is described in detail below with reference to the drawings. Some of the drawings referred to in the following description are enlarged views of characteristic portions, which are enlarged for convenience of making the characteristics of the present invention understood easier, and the ratios of the dimensions of components to one another and the like may differ from actuality. The materials, dimensions, and the like given in the following description are an example, and the present invention is not limited thereto. The present invention can be carried out in suitably adjusted modes without losing the effects of the present invention.

### First Embodiment

### Configuration of Semiconductor Device

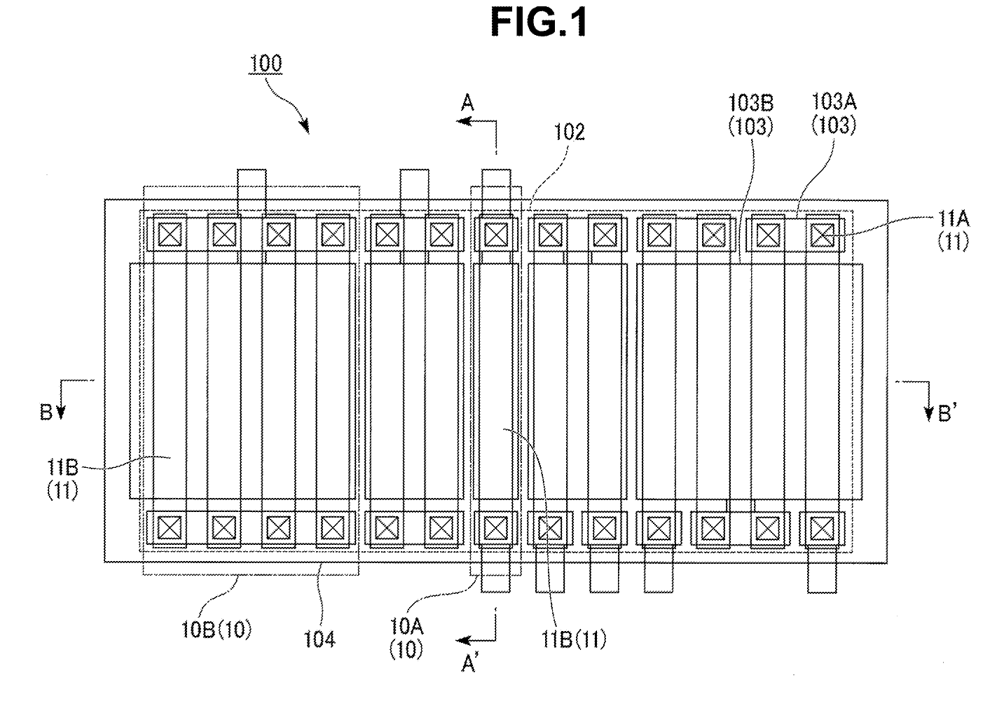

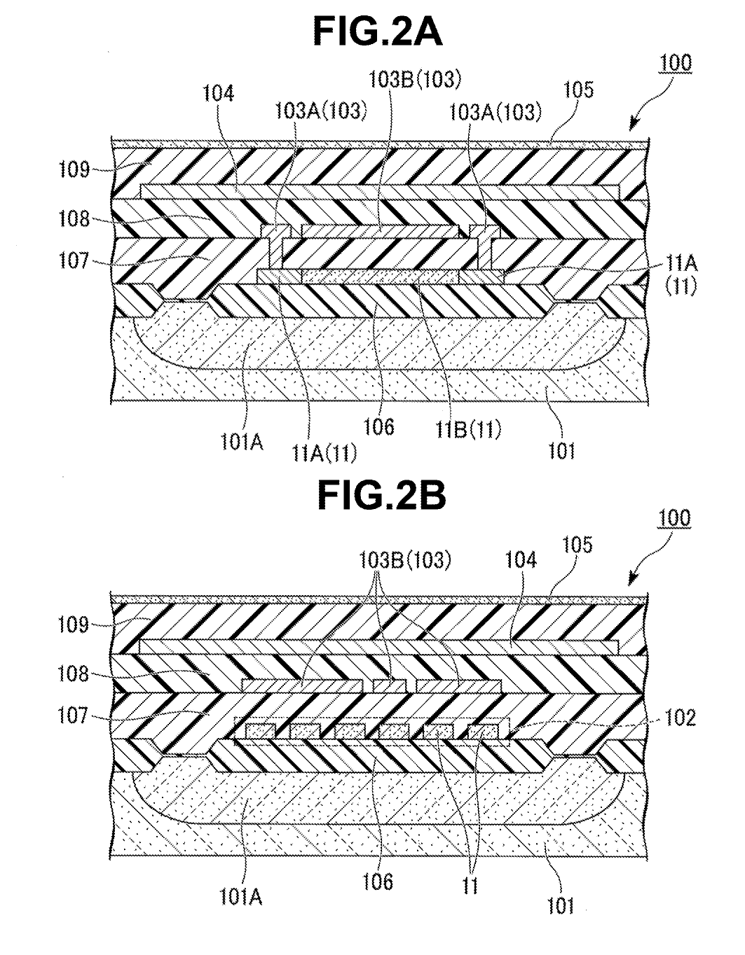

FIG. 1 is a plan view of a semiconductor device 100 according to a first embodiment of the present invention. FIG. 2A and FIG. 2B are sectional views of the semiconductor device 100 taken along the line A-A′ and the line B-B′ of FIG. 1, respectively.

The semiconductor device 100 includes, as main components, a substrate (base material) 101, a bleeder resistor circuit element 102 formed on one main surface side of the substrate 101, two metal films (first metal film 103 and second metal film 104) formed above the bleeder resistor circuit element 102, and a silicon nitride film 105 formed above the second metal film 104.

Insulating films 106, 107, and 108 are formed between the substrate 101 and the bleeder resistor circuit element 102, between the bleeder resistor circuit element 102 and the first metal film 103, and between the first metal film 103 and the second metal film 104, respectively. An insulating film 109 may be formed between the second metal film 104 and the silicon nitride film 105. In FIG. 1, in order to clarify the configurations of the bleeder resistor circuit element 102 serving as a main portion and the periphery thereof, the illustration of the substrate, the insulating films, the silicon nitride film, and the like is omitted.

The semiconductor device 100 illustrated in FIG. 2A and FIG. 2B uses the n-type substrate 101 having a p-type well 101A formed on one main surface side, and has a two-layer wiring structure. The bleeder resistor circuit element 102 is arranged on an insulating film (field insulating film) 106 formed on a surface of the p-type well 101A.

The configuration of the semiconductor device 100 is not limited to that illustrated in FIG. 2A and FIG. 2B. The semiconductor device 100 may include elements other than the bleeder resistor circuit element 102 or have a wiring structure of two or more layers in accordance with the application. Further, the conductivity type of impurities to be doped into the substrate can be freely set.

The bleeder resistor circuit element 102 includes a plurality of polycrystalline silicon resistor units 10. Each of the polycrystalline silicon resistor units 10 is formed of one or both of a single polycrystalline silicon resistor 11 exhibiting a desired resistance value and a plurality of polycrystalline silicon resistors 11 connected to each other so as to exhibit the desired resistance value. The polycrystalline silicon resistor 11 is doped with p-type or n-type impurities.

That is, the bleeder resistor circuit element 102 may include only polycrystalline silicon resistor units 10A each being formed of the single polycrystalline silicon resistor 11, only polycrystalline silicon resistor units 10B each being formed of the plurality of polycrystalline silicon resistors 11, or a combination of both the polycrystalline silicon resistor units 10A and the polycrystalline silicon resistor units 10B. In FIG. 1, there is illustrated a case in which the bleeder circuit resistor element 102 includes a combination of both the polycrystalline silicon resistor unit 10A and the polycrystalline silicon resistor units 10B.

As the first metal film 103, for example, an Al—Si—Cu film or an Al—Cu film is used, and it is preferred that the thickness thereof fall within a range of about 3,000 Å or more and about 5,000 Å or less.

The first metal film 103 is divided into a plurality of films so as to individually cover the plurality of polycrystalline silicon resistor units 10. That is, at least one first metal film 103 is formed above any of the polycrystalline silicon resistor units 10. The first metal films 103 formed above the adjacent polycrystalline silicon resistor units 10 are separated from each other.

Each of the plurality of first metal films 103 is further divided into portions (electrode lead-out layers) 103A for covering electrode portions 11A of the polycrystalline silicon resistor unit 10, and portions (cover layers) 103B for covering high-resistance portions 11B of the polycrystalline silicon resistor unit 10 other than the electrode portion 11A. The electrode portion 11A is positioned at an end portion of each polycrystalline silicon resistor 11 and doped with impurities in a concentration higher than that of the high-resistance portion 11B.

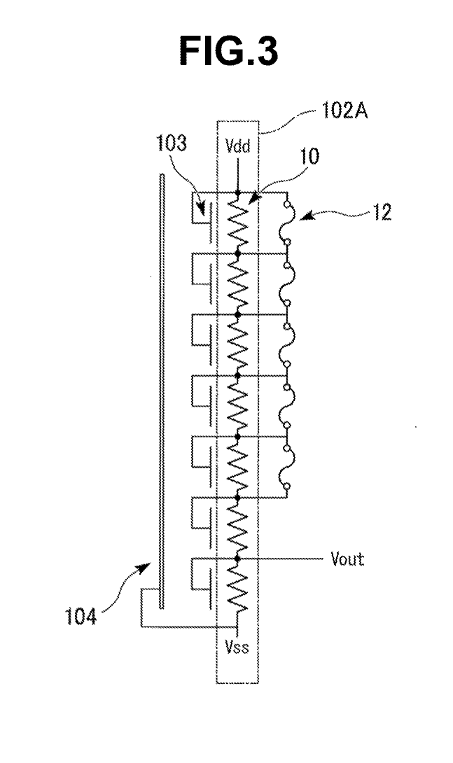

FIG. 3 is a diagram of a bleeder resistor circuit 102A configured to cause the semiconductor device 100 to operate and a peripheral circuit thereof. In the bleeder resistor circuit 102A, the plurality of polycrystalline silicon resistor units 10 are connected to each another in series, and a fuse circuit element 12 is connected in parallel to the corresponding polycrystalline silicon resistor unit 10.

The cover layer 103B is connected to the polycrystalline silicon resistor unit 10 that is covered with the cover layer 103B, through metal wiring. That is, one cover layer 103B is electrically connected to one polycrystalline silicon resistor unit 10 that is covered with the one cover layer 103B. Consequently, the cover layer 103B and the corresponding polycrystalline silicon resistor unit 10 have an equal potential even when different power supply voltages V_{dd} and Vₛₛ (V_{dd}>Vₛₛ) are applied to one end side and the other end side of the bleeder resistor circuit 102A, in which the plurality of polycrystalline silicon resistor units 10 are connected to each other in series, to generate a potential difference between the one end side and the other end side.

A material for a metal wire for connecting the polycrystalline silicon resistor unit 10 to the cover layer 103B may be the same as that for the first metal film 103 or a high-melting-point metal, for example, tungsten.

As the second metal film 104, for example, an Al—Si—Cu film or an Al—Cu film is used, and it is preferred that the thickness thereof fall within a range of about 3,000 Å or more and about 10,000 Å or less.

The second metal film 104 is an integral film having a large area, for covering the entirety of the bleeder resistor circuit element 102 including the electrode portions 11A in a seamless manner with the first metal films 103 interposed between the second metal film 104 and the bleeder resistor circuit element 102. The second metal film 104 has a potential grounded to V_{SS}.

The semiconductor device 100 according to the first embodiment includes the plurality of first metal films 103 that are individually connected to the plurality of polycrystalline silicon resistor units 10, and further includes the second metal film 104 having a large area, for covering the entirety of the bleeder resistor circuit element 102 with the first metal films 103 interposed between the second metal film 104 and the bleeder resistor circuit element 102. Through arrangement of the first metal film 103, the potential difference between the polycrystalline silicon resistor unit 10 and the first metal film 103 is constant irrespective of the layout of components. As a result, the issue of the variation in resistance value change between the polycrystalline silicon resistor units 10 can be avoided.

Further, through arrangement of the second metal film 104, the issue of penetration of hydrogen into the bleeder resistor circuit element 102 can be avoided in a manufacturing process. As a result, in the semiconductor device 100 according to the first embodiment, the amount of hydrogen contained in the bleeder resistor circuit element 102 is significantly reduced as compared to the related art.

The second metal film 104 is formed on an upper layer side of the first metal film 103. The second metal film 104 is not required to be divided for the electrode portion 11A and the high-resistance portion 11B of the corresponding polycrystalline silicon resistor unit 10 unlike the first metal film 103, and can be formed into a shape covering the entire bleeder resistor circuit 102A including the periphery of the electrode portions 11A without a gap. As a result, in the semiconductor device 100 according to the first embodiment, a hydrogen penetration path to an end portion of the polycrystalline silicon resistor 11 at which the electrode portion 11A is formed, as well as a hydrogen penetration path to the high-resistance portion 10B of the polycrystalline silicon resistor 11 can be shielded, with the result that a decrease in yield associated with the disturbance of the resistance division ratio of the bleeder resistor circuit element 102 can be prevented.

It is preferred that the second metal film 104 have an outermost periphery located on an outer side of an outermost periphery of the bleeder resistor circuit element 102 in plan view from the silicon nitride film 105 side. In this case, part of hydrogen that is to obliquely penetrate the bleeder resistor circuit element 102, as well as hydrogen that is to perpendicularly penetrate the bleeder resistor circuit element 102 from an upper layer side thereof can be blocked by the second metal film 104. The function of protecting the bleeder resistor circuit element 102 from hydrogen can be enhanced correspondingly.

In a related-art structure, it is necessary to positively cover the high-resistance portion with the first metal film, and hence the first metal film is formed in a large size so as to cover a part of a low-resistance portion as well as the high-resistance portion. That is, in the related-art structure, the first metal film has a region overlapping with the low-resistance portion.

In contrast, in the semiconductor device 100 according to the first embodiment, the second metal film 104 has a function of covering the high-resistance portion. It is thus not necessary to form the first metal film 103 in a large size, and the overlapping region between the first metal film 103 and the low-resistance portion can be reduced, with the result that the size of the entire semiconductor device can be reduced correspondingly.

Further, in the related-art structure, a dummy resistor is arranged in a gap between the divided first metal films to securely cover the high-resistance portion with the first metal film. However, in the first embodiment, it is not necessary to arrange such dummy resistor, and hence the size of the entire semiconductor device can be further reduced correspondingly.

### Method of Manufacturing Semiconductor Device

A method of manufacturing the semiconductor device 100 is described mainly regarding a step of forming the bleeder resistor circuit element 102 and a peripheral portion thereof.

First, p-type impurities are doped into one main surface side of an n-type substrate to form a p-type well. Then, a field insulating film is formed by a local oxidation of silicon (LOCOS) method or a shallow trench isolation (STI) method. After that, a region (p⁺ diffusion layer) having a relatively high p-type impurity concentration is formed at a predetermined position in the p-type well.

Next, a polycrystalline silicon (polysilicon) film for forming a bleeder resistor circuit is formed on the field insulating film by a known method, for example, a chemical vapor deposition (CVD) method. Further, the polycrystalline silicon film is patterned so as to have a desired shape and arrangement, to thereby form a plurality of polycrystalline silicon resistors. It is preferred that the thickness of the resistor to be formed be about 500 Å or more and about 5,000 Å or less.

Next, an interlayer insulating film is formed on the polycrystalline silicon resistors by a known method, for example, the CVD method. Then, a contact hole is formed in the interlayer insulating film at a position overlapping with at least a part of a polycrystalline silicon resistor unit formed of a single polycrystalline silicon resistor or a plurality of polycrystalline silicon resistors. Subsequently, a metal film is embedded into the contact hole. A material for the metal film to be embedded may be the same material as that for a first metal film or a high-melting-point metal, for example, tungsten.

Next, the first metal film is formed on the interlayer insulating film having the contact hole formed therein, by a known method, for example, a sputtering method. The first metal film thus formed is divided by patterning so as to correspond to the polycrystalline silicon resistor units in a one-to-one relationship. As a result of this division of the first metal film, a cover layer of the corresponding first metal film is formed for each polycrystalline silicon resistor unit. That is, one polycrystalline silicon resistor unit is covered with one first metal film.

As the first metal film, for example, an Al—Si—Cu film or an Al—Cu film can be used. It is preferred that the thickness of the first metal film is set to fall within a range of about 3,000 Å or more and about 5,000 Å or less.

Next, an interlayer insulating film is formed on the first metal films by a known method, for example, the CVD method, and a second metal film is formed on the interlayer insulating film by a known method, for example, the sputtering method. In this case, the second metal film is formed so as to be an integral film having a large area, for covering at least the entirety of the bleeder resistor circuit element.

As the second metal film, for example, an Al—Si—Cu film or an Al—Cu film can be used. It is preferred that the thickness of the second metal film be set to fall within a range of about 3,000 Å or more and about 10,000 Å or less.

Finally, a silicon nitride film is formed on the second metal film directly or through intermediation of an oxide film by a plasma CVD method, and thus the semiconductor device 100 according to the first embodiment can be obtained.

### Second Embodiment

### Configuration of Semiconductor Device

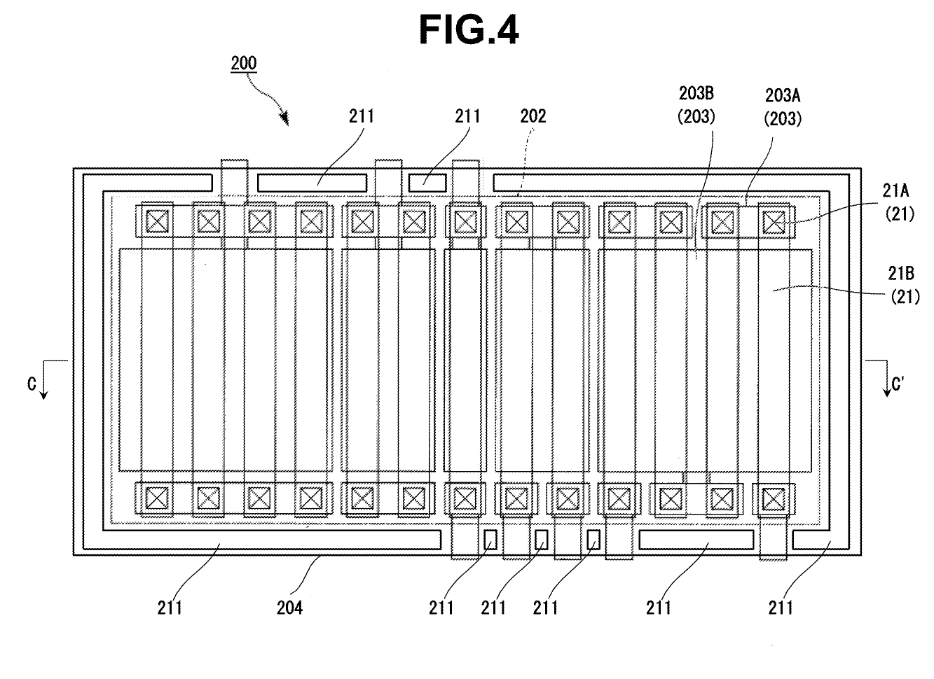

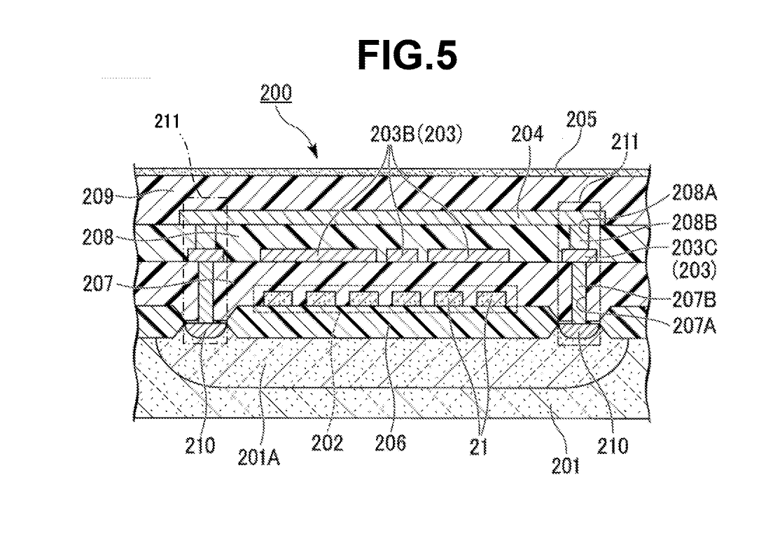

FIG. 4 is a plan view of a semiconductor device 200 according to a second embodiment of the present invention. FIG. 5 is a sectional view of the semiconductor device 200 taken along the line C-C′ of FIG. 4. In FIG. 4, in order to clarify the configurations of a bleeder resistor circuit element serving as a main portion and the periphery thereof, the illustration of a substrate, insulating films, a silicon nitride film, and the like is omitted.

The semiconductor device 200 has a side wall portion 211. The side wall portion 211 is formed upright on a periphery (outermost periphery) of a bleeder resistor circuit element 202, and has a top portion connected to a second metal film 204 and a bottom portion connected to a substrate 201. A p-type high-concentration diffusion layer (p⁺ diffusion layer) 210 is formed in a portion of the surface of the substrate 201 which is connected to the side wall portion 211. The configuration of the semiconductor device 200 other than the side wall portion 211 is the same as that of the semiconductor device 100 according to the first embodiment, and the semiconductor device 200 exhibits the same effects as those of the semiconductor device 100.

The side wall portion 211 includes a first metal film 203C, metal films 207B and 208B, and the p-type high-concentration diffusion layer (p⁺ diffusion layer) 210 all of which are stacked. The metal films 207B and 208B are embedded in contact holes (first connection hole 207A and second connection hole 208A) formed in insulating films 207 and 208 on a lower layer side and an upper layer side of the first metal film 203C, respectively. The p-type high-concentration diffusion layer 210 is formed in a p-type well 201A under the first connection hole 207A. The first connection hole 207A connects the substrate 201 and the first metal film 203C to each other, and the second connection hole 208A connects the first metal film 203C and the second metal film 204 to each other. The p-type high-concentration diffusion layer 210 surrounds the periphery of the bleeder resistor circuit element 202 in plan view from an outermost surface side of the semiconductor device 200.

It is preferred that the side wall portions 211 be arranged at short intervals in plan view from a silicon nitride film 205 side, and it is more preferred that the side wall portion 211 surrounds the bleeder resistor circuit element 202 in a seamless manner.

Through arrangement of the side wall portion 211, the semiconductor device 200 can block hydrogen that is to penetrate the bleeder resistor circuit element 202 by coming around from the side, as well as hydrogen that is to linearly penetrate the bleeder resistor circuit element 202 from above, with the result that the bleeder resistor circuit element 202 can be more strongly protected.

Further, the side wall portion 211 blocks penetration of hydrogen from the side, and hence the second metal film 204 may be required to block only hydrogen that is to linearly penetrate the bleeder resistor circuit element 202 from above. Thus, the area of the second metal film 204 can be set to be substantially the same as that of the bleeder resistor circuit element 202, and the size of the entire semiconductor device can be reduced as compared to the case in which there is no side wall portion 211.

### Third Embodiment

### Configuration of Semiconductor Device

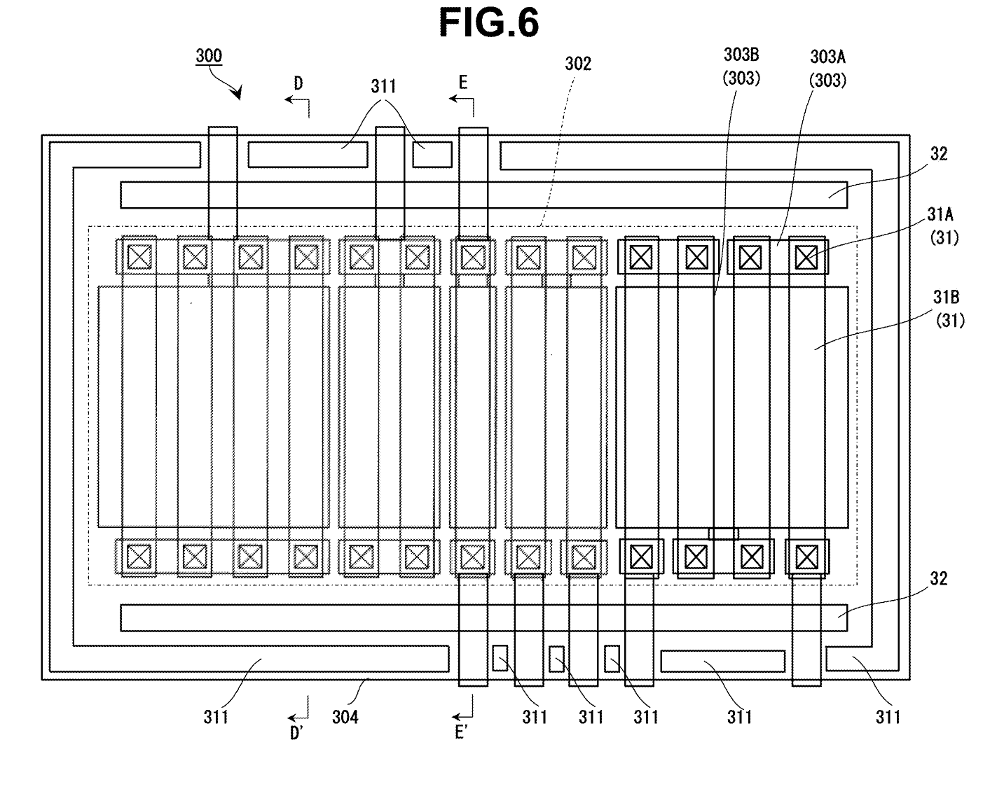

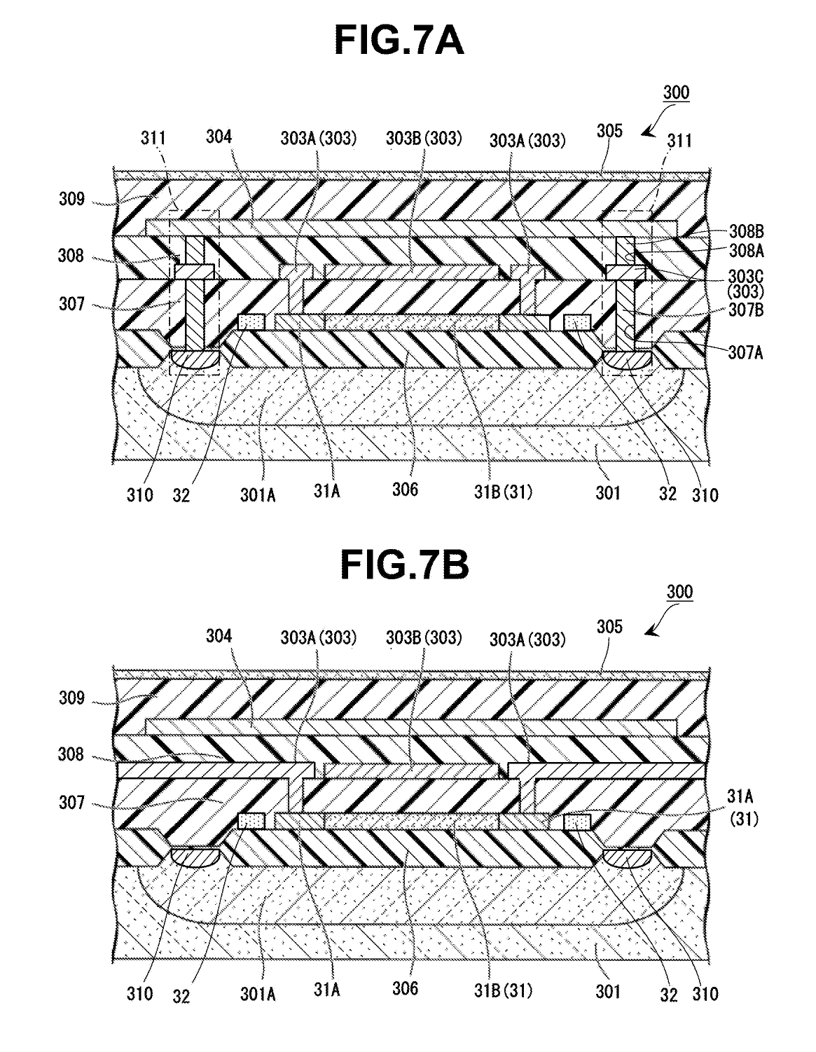

FIG. 6 is a plan view of a semiconductor device 300 according to a third embodiment of the present invention. FIG. 7A and FIG. 7B are sectional views of the semiconductor device 300 taken along the line D-D′ and the line E-E′ of FIG. 6, respectively. In FIG. 6, in order to clarify the configurations of a bleeder resistor circuit element serving as a main portion and the periphery thereof, the illustration of a substrate, insulating films, a silicon nitride film, and the like is omitted.

The semiconductor device 300 has a side wall portion 311. The side wall portion 311 is formed upright on a periphery (outermost periphery) of a bleeder resistor circuit element 302, and has a top portion connected to a second metal film 304 and a bottom portion connected to a substrate 301 in the same manner as in the second embodiment. On an inner side of a region in which the side wall portion 311 is formed in the semiconductor device 300, the configuration of the bleeder resistor circuit element 302 is the same as that of the semiconductor device 100 according to the first embodiment.

As illustrated in FIG. 7A, the third embodiment is the same as the second embodiment also in the following configuration. Specifically, the side wall portion 311 includes a first metal film 303C, metal films 307B and 308B, and a p-type high-concentration diffusion layer (p⁺ diffusion layer) 310 all of which are stacked. The metal films 307B and 308B are embedded in contact holes (first connection hole 307A and second connection hole 308A) formed in insulating films 307 and 308 on a lower layer side and an upper layer side of the first metal film 303C, respectively. The p-type high-concentration diffusion layer 310 is formed in a p-type well 301A under the first connection hole 307A. The first connection hole 307A connects the substrate 301 and the first metal film 303C to each other, and the second connection hole 308A connects the first metal film 303C and the second metal film 304 to each other. The p-type high-concentration diffusion layer 310 surrounds the periphery of the bleeder resistor circuit element 302 in plan view from an outermost surface side of the semiconductor device 300. That is, with the above-mentioned configurations, the same effects as those of the first embodiment and the second embodiment can be obtained.

In the vicinity of the line E-E′ of FIG. 6, in order to connect an electrode lead-out layer 303A connected to an electrode portion 31A to another circuit element portion (not shown), the side wall portion 311 has discontinuous parts each in a region in which the electrode lead-out layer 303A extends toward an outer side of the bleeder resistor circuit element 302.

In the third embodiment, the semiconductor device 300 further includes polycrystalline silicon covers 32 each in a region between a region in which the bleeder resistor circuit element 302 is formed and a region in which the side wall portion 311 is formed. The polycrystalline silicon cover 32 is arranged in a region on the outer side of the bleeder resistor circuit element 302 and in the discontinuous part of the side wall portion 311 so as to compensate for the discontinuous part of the side wall portion 311 in plan view. In FIG. 6, in the region on the outer side of the bleeder resistor circuit element 302, the polycrystalline silicon covers 32 are arranged linearly so as to be in parallel to right and left side of the bleeder resistor circuit element 302 on which the electrode portions 31A are arranged.

As illustrated in the sectional view of FIG. 7B, the polycrystalline silicon covers 32, each of which is formed of the same polycrystalline silicon layer as that of the polycrystalline silicon resistor 31, are formed on both sides of the polycrystalline silicon resistors 31 on a field insulating film 306. In a region above the polycrystalline silicon cover 32, the electrode lead-out layer 303 extends outward beyond the region in which the second metal film 304 is formed, and the side wall portion 311 cannot be formed in this region. Consequently, there is a risk in that hydrogen may penetrate the polycrystalline silicon resistor 31 through the discontinuous part of the side wall portion 311. The polycrystalline silicon cover 32 can absorb hydrogen that penetrates the polycrystalline silicon resistor 31 through the discontinuous part of the side wall portion 311, to thereby reduce hydrogen reaching the polycrystalline silicon resistor 31.

In general, unlike monocrystalline silicon, polycrystalline silicon has a grain portion having high crystallinity in which silicon atoms are regularly bonded to each other and, as a boundary portion between the grain portions, a grain boundary portion having low crystallinity in which silicon atoms are irregularly arranged. In the grain boundary portion, there are a large number of atoms having dangling bonds. Hydrogen is liable to be bonded to the dangling bonds of the atoms, and hence the resistance value of the polycrystalline silicon resistor varies depending on a bonding variation. In view of the above-mentioned property, the polycrystalline silicon cover 32 illustrated in FIG. 6 is arranged in the region on the outer side of the bleeder resistor circuit element 302 so as to absorb hydrogen penetrating from outside of the polycrystalline silicon cover 32, to thereby suppress penetration of hydrogen into the region on an inner side of the region in which the polycrystalline silicon cover 32 is formed.

Through arrangement of the polycrystalline silicon covers 32 in the vicinity of the discontinuous parts of the side wall portion 311 in addition to the second metal film 304 and the side wall portion 311, the semiconductor device 300 can suppress penetration of hydrogen from outside and more strongly protect the bleeder resistor circuit element 302 than in the second embodiment.

In FIG. 6, in the region on the outer side of the bleeder resistor circuit element 302, the polycrystalline silicon cover 32 is linearly arranged so as to be in parallel to right and left side of the bleeder resistor circuit element 302 on which the electrode portions 31A are arranged. However, the present invention is not limited to this configuration. That is, the polycrystalline silicon cover 32 may be partially arranged in the vicinity of in the discontinuous part of the side wall portion 31. Further, in plan view, when the side wall portion 311 has discontinuous parts in the region on the outer side of the bleeder resistor circuit element 302 and in regions along upper and lower side of the bleeder resistor circuit element 302 on which the electrode portions 31A are not arranged, the polycrystalline silicon covers 32 are arranged in those regions. Meanwhile, the polycrystalline silicon cover 32 may be arranged in a seamless manner so as to surround the entire periphery of the bleeder resistor circuit element 302. With this, unintended penetration of hydrogen from any direction can be suppressed, and a resistance value variation of the polycrystalline silicon resistor 31 can be suppressed.

Further, when the thickness of the polycrystalline silicon cover 32 is larger than that of the polycrystalline silicon resistor 31, the number of directions of hydrogen penetration can be reduced, and hence the effect of blocking hydrogen becomes higher. In FIG. 7A and FIG. 7B, the polycrystalline silicon resistor 31 and the polycrystalline silicon cover 32 are formed of the same polycrystalline silicon layer, and hence the thicknesses of the polycrystalline silicon resistor 31 and the polycrystalline silicon cover 32 cannot be made different. However, the difference in thickness can be achieved by forming the polycrystalline silicon cover 32 of a polycrystalline silicon layer different from that of the polycrystalline silicon resistor 31. As long as the polycrystalline silicon cover 32 is formed of a polycrystalline silicon layer different from that of the polycrystalline silicon resistor 31, and the thickness of the polycrystalline silicon cover 32 is larger than that of the polycrystalline silicon resistor 31, for example, a polycrystalline silicon layer to be used in a gate electrode of a field effect transistor or a polycrystalline silicon layer to be used in a fuse for adjusting a resistance value may be used (not shown).

What is claimed is:

1. A semiconductor device, comprising:
a substrate;
a bleeder resistor circuit element formed on one main surface side of the substrate, and including a plurality of polycrystalline silicon resistor units;
a first metal film divided into a plurality of films so as to individually cover the plurality of polycrystalline silicon resistor units;
an integral second metal film formed above the first metal film so as to cover an entirety of the bleeder resistor circuit element; and
a silicon nitride film formed above the integral second metal film,
each of the plurality of films of the first metal film including a first part for covering an electrode portion of a corresponding one of the plurality of polycrystalline silicon resistor units, and a second part for covering a portion other than the electrode portion, and
the second part being electrically connected to the corresponding one of the plurality of polycrystalline silicon resistor units that is covered with the each of the plurality of films of the first metal film.

2. A semiconductor device according to claim 1, wherein the integral second metal film has an outermost periphery located on an outer side of an outermost periphery of the bleeder resistor circuit element in plan view from the silicon nitride film side.

3. A semiconductor device according to claim 1, further comprising a side wall portion formed upright on a periphery of the bleeder resistor circuit element, and is connected to the integral second metal film.

4. A semiconductor device according to claim 2, further comprising a side wall portion formed upright on a periphery of the bleeder resistor circuit element, and is connected to the integral second metal film.

5. A semiconductor device according to claim 3,
wherein the semiconductor device has a first connection hole for connecting the substrate and the first metal film to each other, and a second connection hole for connecting the first metal film and the integral second metal film to each other, and
wherein the side wall portion is formed of a metal film embedded in the first connection hole and a metal film embedded in the second connection hole.

6. A semiconductor device according to claim 4,
wherein the semiconductor device has a first connection hole for connecting the substrate and the first metal film to each other, and a second connection hole for connecting the first metal film and the integral second metal film to each other, and
wherein the side wall portion is formed of a metal film embedded in the first connection hole and a metal film embedded in the second connection hole.

7. A semiconductor device according to claim 3, further comprising, in plan view, a polycrystalline silicon cover in a region between a region in which the bleeder resistor circuit element is formed and a region in which the side wall portion is formed.

8. A semiconductor device according to claim 4, further comprising, in plan view, a polycrystalline silicon cover in a region between a region in which the bleeder resistor circuit element is formed and a region in which the side wall portion is formed.

9. A semiconductor device according to claim 5, further comprising, in plan view, a polycrystalline silicon cover in a region between a region in which the bleeder resistor circuit element is formed and a region in which the side wall portion is formed.

10. A semiconductor device according to claim 6, further comprising, in plan view, a polycrystalline silicon cover in a region between a region in which the bleeder resistor circuit element is formed and a region in which the side wall portion is formed.
